(19) United States
(12) Patent Application Publication
(10) Pub. No.: US 2011/0080932 A1
(43) Pub. Date: Apr. 7, 2011

(54) Laser diode and laser diode device

(75) Inventors: Masaru Kuramoto, Miyagi (JP); Takeharu Asano, Kanagawa (JP)

(73) Assignee: Sony corporation, Tokyo (JP)

(21) Appl. No.: 12/926,598

(22) Filed: Nov. 29, 2010

Related U.S. Application Data
(63) Continuation of application No. 11/521,429, filed on Sep. 15, 2006, now abandoned.

(30) Foreign Application Priority Data
Sep. 16, 2005 (JP) 2005-269904

(51) Int. Cl. H01S 5/22; H01S 5/20

(52) U.S. Cl. 372/46.012; 372/46.01; 372/46.015

(57) ABSTRACT

A laser diode capable of being easily mounted, and a laser diode device in which the laser diode is mounted are provided. A hole is disposed in a semiconductor layer, and a p-type electrode and an n-type semiconductor layer are electrically connected to each other by a bottom portion (a connecting portion) of the hole. Thereby, the p-type electrode has the same potential as the n-type semiconductor layer, and a saturable absorption region is formed in a region corresponding to a current path. Light generated in a gain region (not shown) is absorbed in the saturable absorption region to be converted into a current. The current is discharged to a ground via the p-side electrode and the bottom portion, and an interaction between the saturable absorption region and the gain region is initiated, thereby self-oscillation can be produced.

### CROSS REFERENCES TO RELATED APPLICATIONS

The present application is a Continuation of application Ser. No. 11/521,429, filed Sep. 15, 2006, which invention contains subject matter related to Japanese Patent Application JP 2005-269904 filed in the Japanese Patent Office on Sep. 16, 2005, the entire contents of which being incorporated herein by reference.

### BACKGROUND OF THE INVENTION

1. Field of the Invention

The present invention relates to a laser diode including two or more separated electrodes on a semiconductor layer and a laser diode device including the laser diode, and more specifically to a laser diode and a laser diode device capable of producing self-oscillation.

2. Description of the Related Art

In recent years, as a low-noise laser diode (LD), a pulsation laser has been a focus of attention. The pulsation laser is a laser oscillating while generating self-excited vibration, and having low coherence and low optical feedback noise, so the pulsation laser is useful specifically for optical disks. For example, as described in Japanese Unexamined Patent Application Publication Nos. 2004-7002 and 2004-186678, the pulsation laser includes two p-side electrodes separated from each other in a resonator direction, and one (hereinafter referred to as “a first electrode”) of the p-side electrodes is grounded, or a reverse bias is applied to the p-side electrode, and a forward bias is applied to the other p-side electrode (hereinafter referred to as “a second electrode”), thereby a saturable absorption region and a gain region are formed in a region corresponding to the first electrode and a region corresponding to the second electrode, respectively, and these regions cause an interaction, thereby self-oscillation is produced.

### SUMMARY OF THE INVENTION

To apply a voltage which is different from a voltage applied to a second electrode is applied to a first electrode, for example, it is necessary to bond a wire to the first electrode for supplying a desired voltage. Typically, an area of approximately 100 μm square is necessary to bond a wire; however, the first electrode typically does not have such a wide area, so it is very difficult to bond the wire to the first electrode. As described above, in techniques described in Japanese Unexamined Patent Application Publication Nos. 2004-7002 and 2004-186678, an advanced mounting technique is necessary.

In view of the foregoing, it is desirable to provide a laser diode which can be easily mounted and a laser diode device in which the laser diode is mounted.

According to an embodiment of the invention, there is provided a laser diode including: a semiconductor layer formed through laminating a first conductive type layer, an active layer and a second conductive type layer, the second conductive type layer including a striped current confinement structure in a top portion thereof, a plurality of electrodes being formed on the second conductive type layer side of the semiconductor layer, and being electrically connected to the second conductive type layer at predetermined intervals; and a connecting portion being disposed in the semiconductor layer so as to be electrically isolated from the active layer, and electrically connecting an electrode of the plurality of electrodes except for at least one and the first conductive type layer to each other.

In the laser diode according to the embodiment of the invention, an electrode of the plurality of electrodes except for at least one and the first conductive type layer are electrically connected to each other by the connecting portion, so the electrode (a first electrode) has the same potential as the first conductive type layer. Thereby, a region corresponding to the first electrode functions as a saturable absorption region, and a region corresponding to an electrode (a second electrode) of the plurality of electrodes except for the first electrode functions as a gain region, and the laser diode produces self-oscillation by an interaction between the regions. Moreover, the connecting portion is formed in the semiconductor layer, and self-oscillation can be produced without bonding a wire connected to a part having the same potential as the first conductive type layer to the first electrode. In other words, it is not necessary to arrange a wire on the first electrode.

In the laser diode according to the embodiment of the invention, a connecting portion is arranged in the semiconductor layer, and the first conductive type layer and the first electrode are electrically connected to each other by the connecting portion, so self-oscillation can be produced without separately arranging a wire on the first electrode. Thereby, as it is not necessary to arrange a wire on the first electrode, the laser diode can be easily mounted. Therefore, a laser diode device in which a heat radiation section, a device or the like is mounted on at least one of the plurality of electrodes side and the first conductive type layer side of the laser diode can be easily manufactured.

Other and further objects, features and advantages of the invention will appear more fully from the following description.

### BRIEF DESCRIPTION OF THE DRAWINGS

FIG. 1 is a perspective view of the structure of a laser diode according to a first embodiment of the invention;

FIG. 2 is a sectional view taken along a line A-A of FIG. 1;

FIG. 3 is a sectional view taken along a line B-B of FIG. 1;

FIGS. 4A, 4B and 4C are sectional views for describing steps of manufacturing the semiconductor shown in FIG. 1;

FIGS. 5A and 5B are sectional views showing steps following FIGS. 4A, 4B and 4C;

FIGS. 6A and 6B are sectional views showing steps following FIGS. 5A and 5B;

FIGS. 7A and 7B are sectional views showing steps following FIGS. 6A and 6B;

FIGS. 8A and 8B are sectional views showing steps following FIGS. 7A and 7B;

FIG. 9 is a side view of a laser diode device according to a modification of the first embodiment;

FIG. 10 is a side view of another laser diode device according to the modification of the first embodiment;

FIG. 11 is a perspective view of the structure of a laser diode device according to a second embodiment of the invention;

FIG. 12 is a sectional view taken along a line C-C of FIG. 11;

FIG. 13 is a sectional view taken along a line D-D of FIG. 11;

FIG. 14 is a plot showing a relationship between a thickness d and a threshold current Ith;

FIG. 15 is a sectional view of the structure of a laser diode according to a first modification of the second embodiment;

FIG. 16 is a perspective view of the structure of a laser diode device according to a second modification of the second embodiment; and

FIG. 17 is a sectional view taken along a line E-E of FIG. 16.

### DETAILED DESCRIPTION OF THE PREFERRED EMBODIMENTS

Preferred embodiments will be described in detail below referring to the accompanying drawings.

### First Embodiment

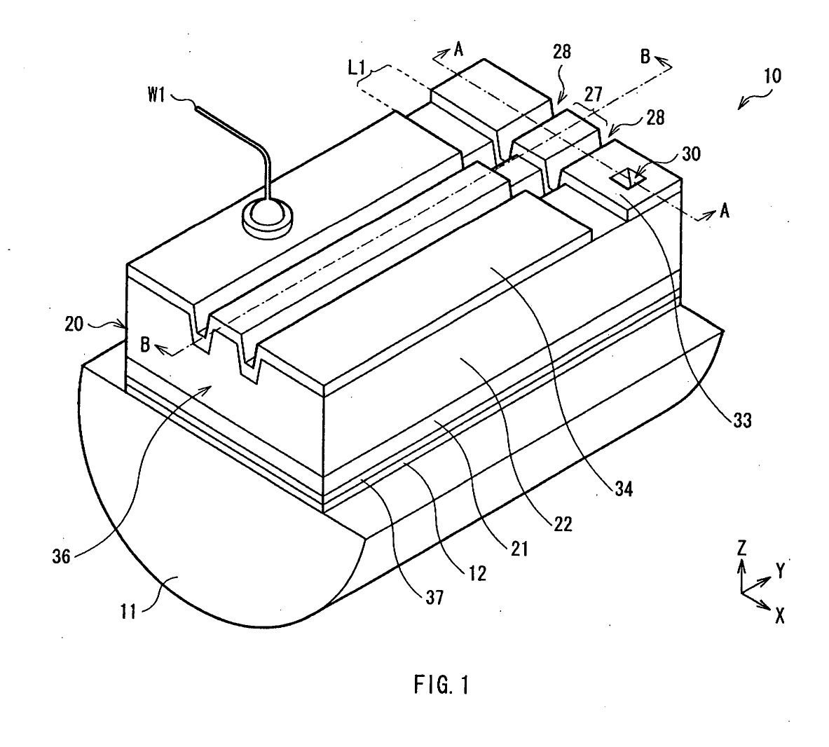

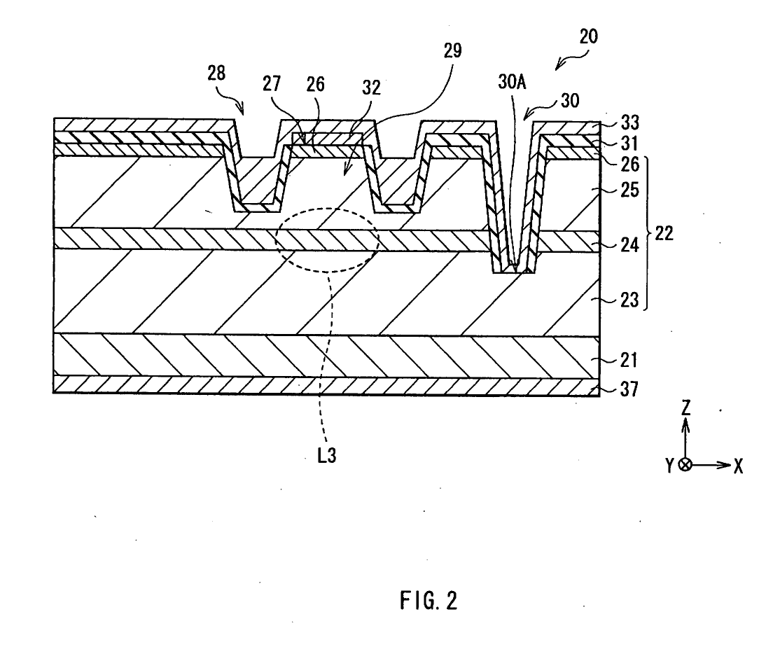

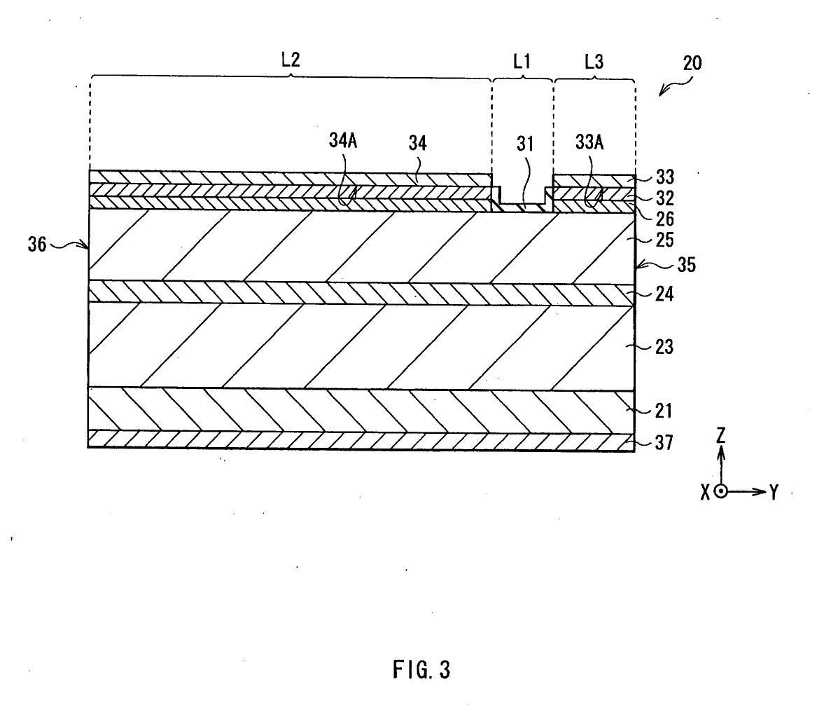

FIG. 1 is a perspective view of the structure of a laser diode device 10 according to a first embodiment of the invention. FIG. 2 is a sectional view taken along an arrow A-A of FIG. 1, and FIG. 3 is a sectional view taken along an arrow B-B of FIG. 1. FIGS. 1 through 3 are schematic views, so dimensions and shapes in FIGS. 1 through 3 are different from actual dimensions and shapes.

The laser diode device 10 is formed through mounting a laser diode 20 on a heat sink 11 (a heat radiation section) with a bonding layer 12 in between so as to face the p-side of the laser diode 20 up. The heat sink 11 is made of, for example, a material having electrical and thermal conductivity such as Cu (copper). The bonding layer 12 fixes the laser diode device 10 and the heat sink 11, and is made of, for example, a bonding material including AuSn or the like. Thereby, heat emitted from the laser diode 20 is dissipated via the heat sink 11, so the laser diode 20 is maintained at an appropriate temperature.

The laser diode 20 is formed through growing a semiconductor layer 22 made of a Group III-V nitride semiconductor on a substrate 21 made of GaN (gallium nitride). The semiconductor layer 22 has a laser structure formed through laminating an n-type cladding layer 23, an active layer 24, a p-type cladding layer 25 and a p-type contact layer 26 in this order. In this case, the n-type cladding layer 23 corresponds to “a first conductive type layer” in the invention, and the p-type cladding layer 25 and the p-type contact layer 26 correspond to “a second conductive type layer” in the invention. Hereinafter, a direction where the above semiconductor layers are laminated is called a vertical direction; a direction where laser light is emitted is called an axial direction; and a direction perpendicular to the axial direction and the vertical direction is called a lateral direction.

The Group III-V nitride semiconductor in this case is a gallium nitride-based compound including gallium (Ga) and nitrogen (N), and examples of the Group III-V nitride semiconductor include GaN, AlGaN (aluminum.gallium nitride), AlGaInN (aluminum.gallium.indium nitride) and so on. They include an n-type impurity of a Group IV or VI element such as Si (silicon), Ge (germanium), O (oxygen) or Se (selenium) or a p-type impurity of a Group II or IV element such as Mg (magnesium) Zn (zinc) or C (carbon), if necessary.

In the semiconductor layer 22, the n-type cladding layer 23 is made of, for example, n-type AlGaN. The active layer 24 has, for example, an undoped GaInN multiquantum well structure. The p-type cladding layer 25 is made of, for example, AlGaN, and the p-type contact layer 26 is made of, for example, p-type GaN.

In a part of the p-type cladding layer 25 and the p-type contact layer 26, a stripe-shaped ridge (a projected rim portion) 27 extending in the axial direction and grooves 28 disposed on both sides of the ridge 27 are formed through selectively etching after forming the p-type contact layer 26 as will be described later. The p-type contact layer 26 is formed only on a top portion of the ridge 27. The ridge 27 and the grooves 28 have a function of limiting the size of a current path 29 in the semiconductor layer 22 and a function of stably maintaining a light mode in the lateral direction into a fundamental (0th) mode, thereby guiding the light mode to the axial direction. The ridge 27 and the grooves 28 correspond to “a current confinement structure” in the invention.

The grooves 28 are formed on both sides of the ridge 27 so as to form a W ridge structure (a current confinement structure), because when the p-type cladding layer 25 is deeply etched over a wide range instead of arranging the grooves 28, electrical leakage easily occurs, and manufacturability is impaired. Moreover, in general, the Group III-V nitride semiconductor is a material which is difficult to be uniformly etched over a wide range, so the ridge 27 is formed through etching in as narrow a range as possible.

In the semiconductor layer 22, a hole 30 having a depth from the p-type cladding layer 25 to the n-type cladding layer 23 is formed. The hole 30 is disposed in a region where a p-side electrode 33 which will be described later is formed at a predetermined distance or over from a region where the W ridge structure is formed in the semiconductor layer 22. The diameter of the hole 30 depends upon the size of a region where the hole 30 can be formed, and is, for example, approximately 10 μm.

An insulating film 31 is formed on a surface of the p-type cladding layer 25 including both side surfaces of the ridge 27 and inner surfaces of the grooves 28 and a side surface of the hole 30. In other words, the active layer 24 in the hole 30 is covered with the insulating film 31, and the top surface of the ridge 27 and a bottom portion 30A (a region where the n-type cladding layer 23 is exposed) of the hole 30 are not covered with the insulating film 31. The insulating film 31 has, for example, a structure in which SiO₂ and Si are laminated in this order.

A p-side contact electrode 32 is formed on the top portion (the p-type contact layer 26) of the ridge 27. In this case, the p-side contact electrode 32 includes Pd (palladium).

A p-side electrode 33 (a first electrode) and a p-side electrode 34 (a second electrode) are formed on a surface including surfaces of the insulating film 31 and the p-side contact electrode 32 and the inner surface of the hole 30 with a separation region L1 in between. The p-side electrode 33 and the p-side electrode 34 have a structure in which Ti (titanium), Pt (platinum) and Au (gold) are laminated in this order. A wire W made of gold or the like is bonded to the p-side electrode 34 so as to be electrically connected to an external power source (not shown) via the wire W.

The p-side electrode 34 is formed in a region where the hole 30 is not formed in a surface including surfaces of the insulating film 31 and the p-side contact electrode 32. Therefore, the p-side electrode 34 is electrically connected to the p-type contact layer 26 of the ridge 27 via the p-side contact electrode 32. Hereinafter, a portion electrically connected to the p-type contact layer 26 of the ridge 27 in the p-side electrode 34 is called a contact portion 34A.

The p-side electrode 33 is formed in a region where the hole 30 is formed in the surface including the surfaces of the insulating film 31 and the p-side contact electrode 32. Therefore, the p-side electrode 33 is electrically connected not only to the p-type contact layer 26 of the ridge 27 via the p-side contact electrode 32 but also to the n-type cladding layer 23 via the bottom portion 30A (a connecting portion). Therefore, the p-side electrode 33 has the same potential as the n-type cladding layer 23. The p-side electrode 33 is isolated from the active layer 24 by the insulating film 31 formed on the side surface of the hole 30. Hereinafter a portion electrically connected to the p-type contact layer 26 of the ridge 27 in the p-side electrode 33 is called a contact portion 33A.

The separation region L1 is a strip-shaped region extending in the lateral direction, and is formed so as to spatially separate the p-side electrode 33 and the p-side electrode 34 from each other in the axial direction and not to electrically short-circuit them. More specifically, in the separation region L1, the p-type contact layer 26 and the p-side contact electrode 32 on the ridge 27 are removed, and its surface (the surface of the p-type cladding layer 25 in the separation region L1) is covered with the insulating film 31. At this time, the width of the separation region L1 in the axial direction is, for example, approximately 10 μm. Moreover, an ion implantation region is preferably formed in a region corresponding to the separation region L1 in the active layer 24 (a region between a region corresponding to the p-side electrode 33 and a region corresponding to the p-side electrode 34 in the active layer 24). Thereby, the resistance becomes higher, and a leakage current at the time of applying a higher voltage can be prevented. The ion implantation region may be formed, for example, through injecting ions including at least one kind selected from the group consisting of silicon (Si), aluminum (Al), oxygen (O) and boron (B).

Thereby, the p-side electrode 34 can inject a current into the active layer 24 via the contact portion 34A, so a region corresponding to the contact portion 34A in the active layer 24 has a function as a gain region L2. On the other hand, the p-side electrode 33 can draw a current (photocurrent) from the active layer 24 via the contact portion 33A and can discharge the current from the active layer 24 via the bottom portion 30A of the hole 30, the n-type cladding layer 23 and the heat sink 11, so a region corresponding to the contact portion 33A in the active layer 24 has a function as a so-called saturable absorption region L3.

In this case, “a function as a gain region L2” means a function of amplifying light emitted by an injected carrier, and “a function as a saturable absorption region L3” means a function of absorbing light emitted in the gain region L2. Therefore, the laser diode 20 according to the embodiment can produce self-oscillation (pulsation) by an interaction between the gain region L2 and the saturable absorption region L3.

The area of the contact portion 33A is set within a size range where the self-oscillation of the laser diode 20 can continue. Therefore, the length of the contact portion 33A in the axial direction is much shorter than the length of the contact portion 34A in the axial direction, and is, for example, approximately 20 μm, so it is extremely difficult to directly bond a wire to the p-side electrode 33. However, as will be described later, the p-side electrode 33 is electrically connected to the n-type cladding layer 23 having the same potential (zero volts) as a ground via the bottom portion 30A, so the p-side electrode 33 can have zero volts without wire bonding. In other words, it is not necessary to directly bond a wire to the p-side electrode 33, so in a step of mounting the laser diode 20, an advanced mounting technique is not necessary.

Moreover, it is only necessary for the contact portion 33A to be disposed in a region sandwiched by a resonator including an emission-side end surface 35 and a reflection-side end surface 36 which will be described later, so the contact portion 33A may be formed so as to correspond to any part of the top portion of the ridge 27; however, as in the embodiment, the contact portion 33A is preferably formed so as to correspond to a part of the top portion of the ridge 27 on the emission-side end surface 35 side. It is because, in the saturable absorption region L3, very little heat is generated, so in the case where the saturable absorption region L3 is disposed on the emission-side end surface 35 side, the degradation of the emission-side end surface 35 can be prevented without arranging a heat radiation mechanism near the emission-side end surface 35.

A pair of the emission-side end surface 35 and the reflection-side end surface 36 are formed on side surfaces perpendicular to a direction where the ridge portion 27 extends (the axial direction). The emission-side end surface 35 is made of, for example, Al₂O₃ (aluminum oxide), and is adjusted so as to have low reflectivity. On the other hand, the reflection-side end surface 36 is formed, for example, through alternately laminating an aluminum oxide layer and a titanium oxide layer, and is adjusted so as to have high reflectivity. Thereby, light generated in the gain region L2 of the active layer 24 travels between the pair of emission-side end surface 35 and the reflection-side end surface 36 so as to be amplified, and then emitted from the emission-side end surface 35 as a beam.

On the other hand, an n-side electrode 37 is disposed on the whole back surface of the substrate 21, and is electrically connected to the substrate 21 and the n-type cladding layer 23. The n-side electrode 37 has, for example, a structure in which titanium (Ti), platinum (Pt) and gold (Au) are laminated in this order. The n-side electrode 37 is electrically connected to the heat sink 11 when the laser diode 20 is mounted on the heat sink 11, so the n-side electrode 37 has the same potential (zero volts) as a ground (not shown) electrically connected to the heat sink 11. Therefore, the n-type cladding layer 23 electrically connected to the n-side electrode 37 and the p-side electrode 33 electrically connected to the n-type cladding layer 23 via the bottom portion 30A have the same potential as the ground as in the case of the n-side electrode 34.

The laser diode device 10 can be manufactured through the following steps.

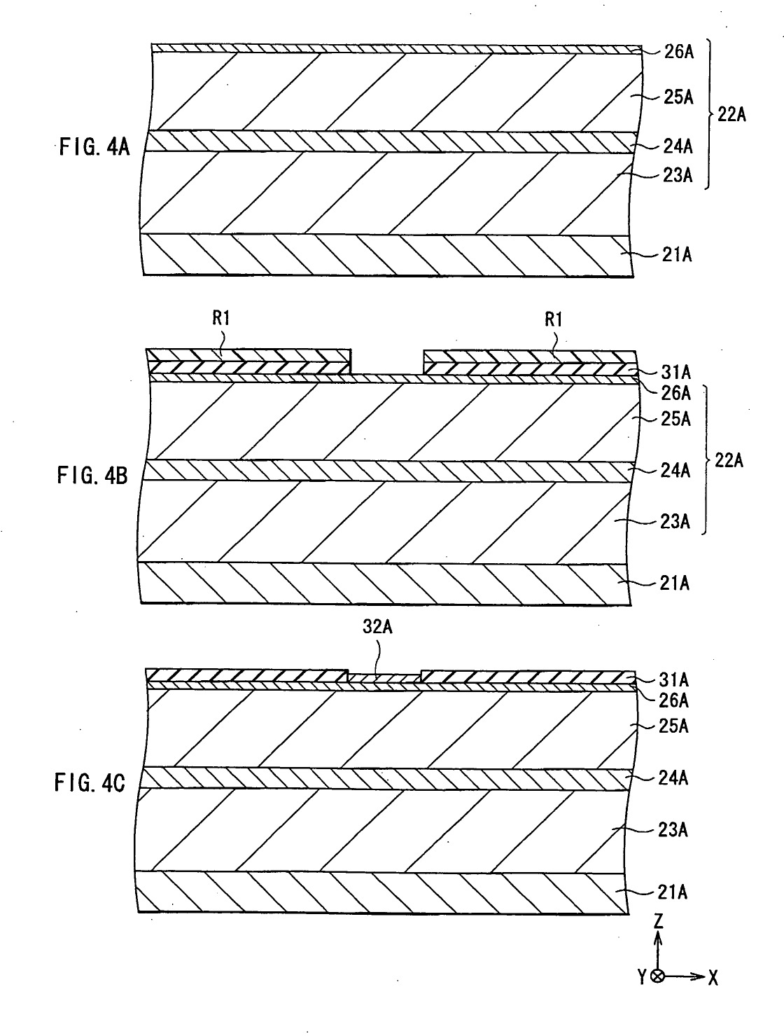

FIGS. 4A through 8B show steps of the manufacturing method in order. To manufacture the laser diode 20, a semiconductor layer 22A made of a Group III-V nitride (a GaN-based compound semiconductor) is formed on a substrate 21A made of GaN by, for example, a MOCVD (Metal Organic Chemical Vapor Deposition) method. At this time, as materials of the GaN-based compound semiconductor, for example, trimethylaluminum (TMA), trimethylgallium (TMG), trimethylindium (TMIn) and ammonia (NH₃) are used, and as the material of a donor impurity, for example, monosilane (SiH₄) is used, and as the material of an acceptor impurity, for example, cyclopentadienyl magnesium (CPMg) is used.

More specifically, at first, an n-type cladding layer 23A, an active layer 24A, a p-type cladding layer 25A and a p-type contact layer 26A are laminated in this order on the substrate 21A (refer to FIG. 4A).

Next, an insulating film 31A made of SiO₂ with a thickness of 0.2 μm is formed on the p-type contact layer 26A. Then, a film made of a photoresist is formed on the insulating film 31A, and a photoresist layer R1 having a stripe-shaped opening which extends in the axial direction is formed by a photolithography technique. Next, the insulating film 31A is selectively removed by a wet etching method using a hydrofluoric acid-based etching solution through the use of the photoresist layer R1 as a mask (refer to FIG. 4B). After that, a metal layer including Pd with a thickness of 100 nm is formed by a vacuum evaporation method. After that, the photoresist layer R1 is removed. Thereby, a p-side contact electrode 32A is formed (refer to FIG. 4C).

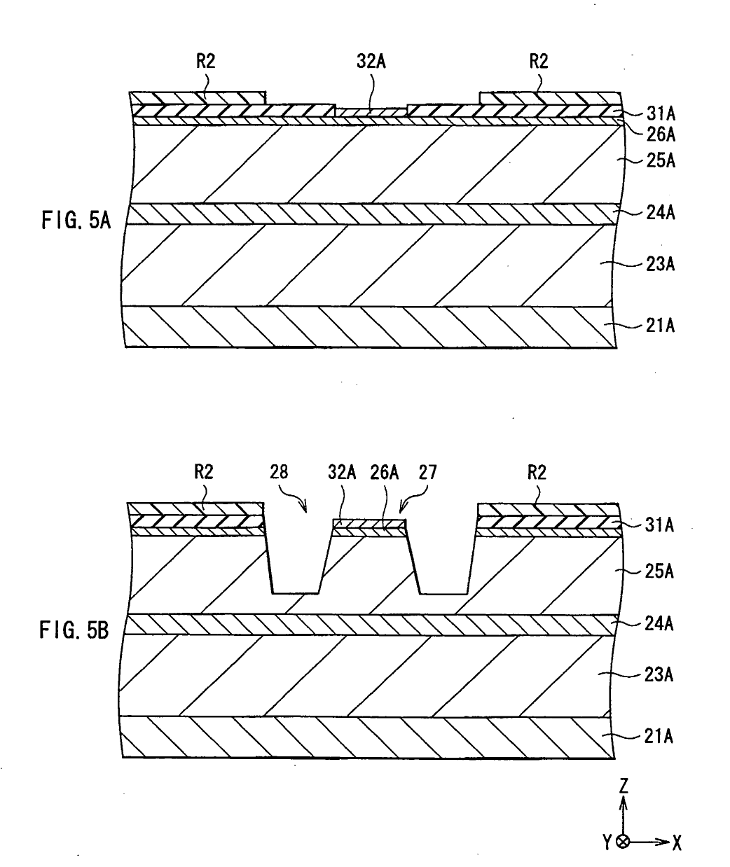

Then, a film made of a photoresist is formed on the p-side contact electrode 32A and the insulating film 31A, and a photoresist layer R2 having an opening in a region where the W ridge structure will be formed is formed by the photolithography technique (refer to FIG. 5A). Next, the insulating film 31A is selectively removed by a wet etching method using a hydrofluoric acid-based etching solution through the use of the photoresist layer R2 and the p-side contact electrode 32A as masks. Next, a part of the p-type contact layer 26A and a part of the p-type cladding layer 25A are selectively removed by a dry etching method using a chlorine-based etching gas (refer to FIG. 5B). After that, the photoresist layer R2 is removed, and a part not covered with the p-side contact electrode 32A of the p-type contact layer 26A is removed. Thereby, the W ridge structure including the stripe-shaped ridge 27 and the grooves 28 is formed in the top portion of the semiconductor layer 22A.

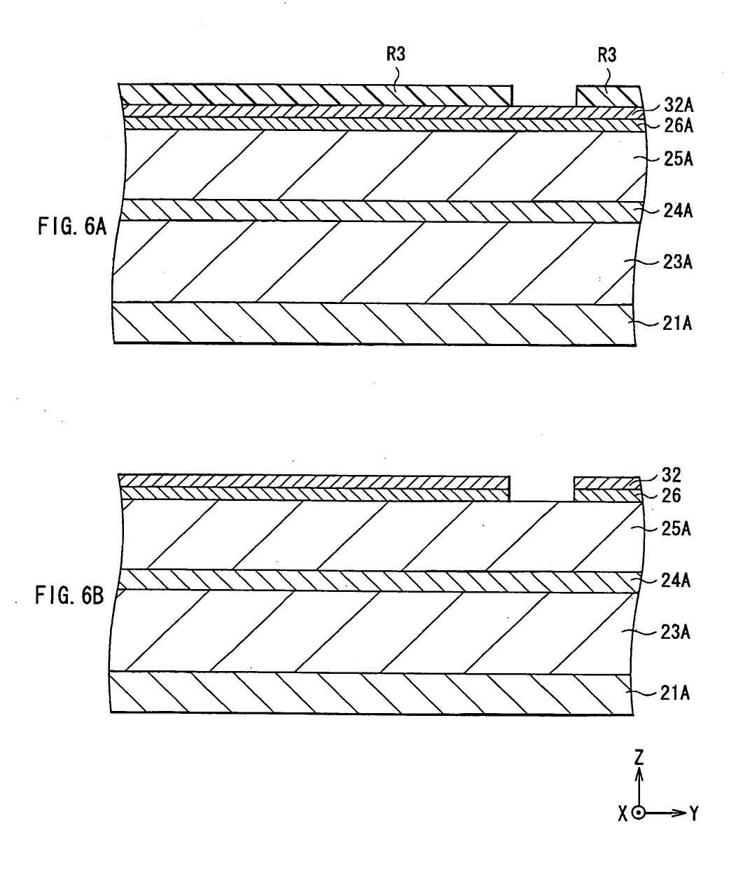

Next, a film made of a photoresist is formed on the whole surface so as to form a photoresist layer R3 having an opening in a region corresponding to the separation region L1 by the photolithography technique (refer to FIG. 6A). Next, the p-side contact electrode 32A is selectively removed by an ion milling method through the use of the photoresist layer R3 as a mask so as to expose the top surface of the p-type contact layer 26A, and then the p-type contact layer 26A is selectively removed by a dry etching method using a chlorine-based etching gas. After that, the photoresist layer R3 is removed. Thereby, a region which will be the separation region L1 is formed, and the p-type contact layer 26 and the p-side contact electrode 32 are formed on the top surface except for a portion which will be the separation region L1 (refer to FIG. 6B).

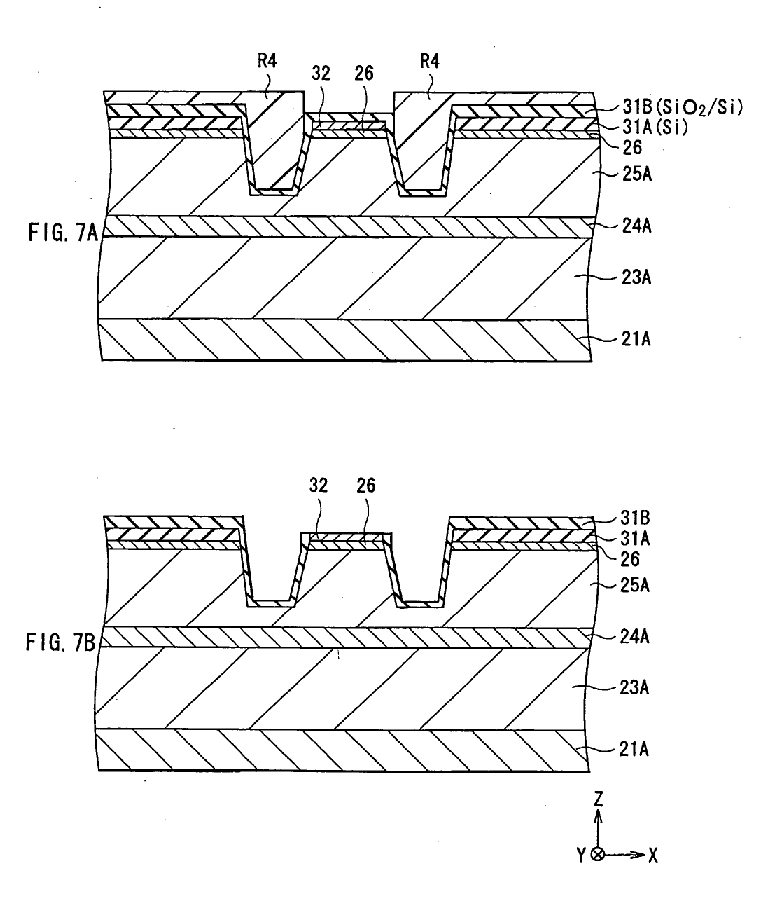

Next, an insulating layer 31B made of SiO₂ with a thickness of 0.2 μm is formed on the whole surface. Then, a film made of a photoresist is formed so that a part of the film on the top of the p-side contact electrode 32 is thinner, and the other part of the film is thicker, that is, the whole surface becomes flat, and then, a photoresist layer R4 having an opening in a region corresponding to the top surface of the p-side contact electrode 32 is formed by the photolithography technique (refer to FIG. 7A). Next, the insulating layer 31B on the p-side contact electrode 32 is etched through the use of the p-side contact electrode 32 as an etching stop layer, thereby the p-side contact electrode 32 is exposed (refer to FIG. 7B).

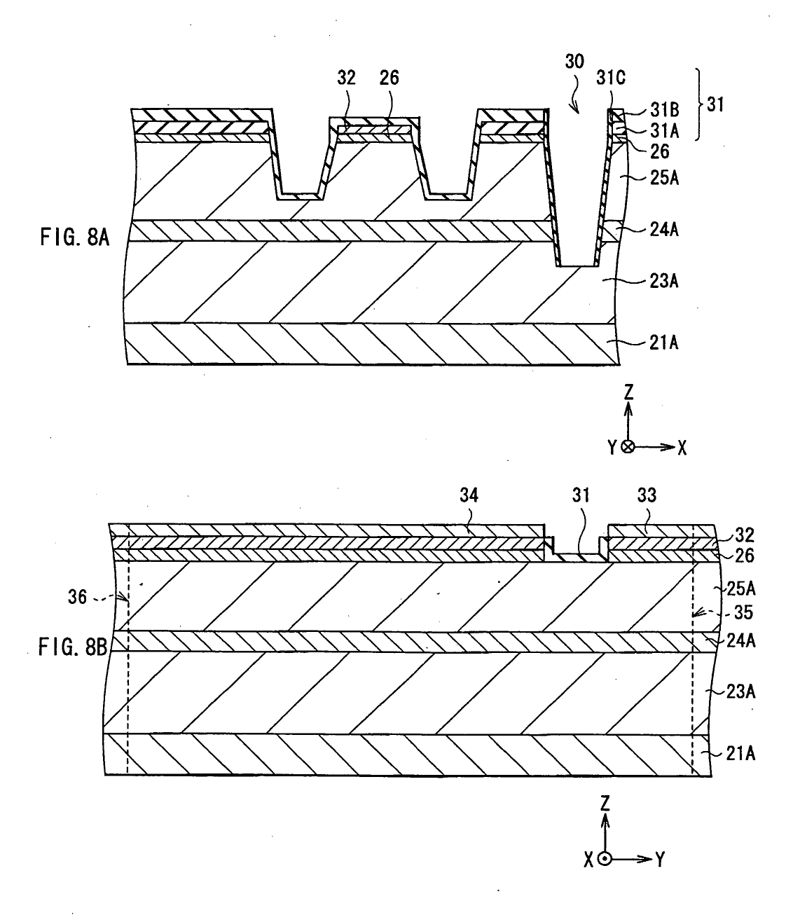

Then, a film made of a photoresist is formed on the whole surface, and a photoresist layer (not shown) having a square-shaped opening is formed in a region where the p-side electrode 33 will be formed at a predetermined distance or over from a region where the W ridge structure is formed by the photolithography technique. Next, the hole 30 having a depth from the p-type cladding layer 25 to the n-type cladding layer 23 is formed by a dry etching method using a chlorine-based etching gas through the use of the photoresist layer as a mask. After that, the photoresist layer is removed. Then, an insulating layer 31C made of SiO₂ is formed on the inner surface of the hole 30, and a portion corresponding to the bottom portion 30A of the insulating layer 31C is selectively removed. Thereby, the insulating layer 31 having an opening in a region corresponding to the p-side contact electrode 32 and the bottom portion 30A is formed (refer to FIG. 8A).

After that, a film made of a photoresist is formed on the whole surface, and a photoresist layer (not shown) is formed in a region corresponding to the separation region L1 by the photolithography technique. Then, for example, Ti, Pt and Au are laminated in this order through the use of an evaporation apparatus. After that, the photoresist layer is removed. Thereby, the p-side electrode 33 and the p-side electrode 34 are formed on the emission-side end surface 35 side and the reflection-side end surface 36 side, respectively (refer to FIG. 8B).

Next, the back surface of the substrate 21A is polished as necessary, and Ti, Pt and Au are laminated in this order on the back surface. Thereby, the n-side electrode 37 is formed. Moreover, the substrate 21A is diced into each element (each laser diode 20). Thus, the laser diode 20 is formed. Further, the wire W is connected to the p-side electrode 34, and the heat sink 11 is bonded to the n-side electrode 37 via the bonding layer 12, thereby the laser diode device 10 is manufactured (refer to FIG. 1).

In the laser diode 20, when a voltage having a predetermined potential difference is applied between the p-side electrode 34 and the n-side electrode 37, a current confined by the ridge 27 is injected into the gain region L2 (a light emission region) of the active layer 24, thereby light emission by electron-hole recombination occurs. The light is reflected by a pair of reflecting mirrors, and causes laser oscillation with a wavelength with a round-trip phase shift of an integral multiple of 2π, and the light is outputted to outside as a beam.

At this time, the p-side electrode 33 is electrically connected to the ground via the bottom portion 30A, thereby the p-side electrode 33 has zero volts. Therefore, light emitted in the gain region L2 is absorbed in the saturable absorption region L3 corresponding to the p-side electrode 33 in the active layer 24 so as to be converted into a current (photocurrent). The current is discharged to the ground via the p-side electrode 33 and the bottom portion 30A. Thereby, an interaction between the gain region L2 and the saturable absorption region L3 is initiated to cause self-oscillation.

Thus, in the laser diode device 20 according to the embodiment, the bottom portion 30A is included in the semiconductor layer 22, and the n-type cladding layer 23 and the p-side electrode 33 are electrically connected to each other via the bottom portion 30A, thereby the p-side electrode 33 can have the same potential (zero volts) as the ground, so self-oscillation can be produced without wire bonding. Moreover, wire bonding on the p-side electrode 33 is not necessary, so the laser diode 20 can be easily mounted. Therefore, in the embodiment, the laser diode device in which the laser diode 20 is mounted on the heat sink 11 or the like can be easily manufactured.

### [Modification]

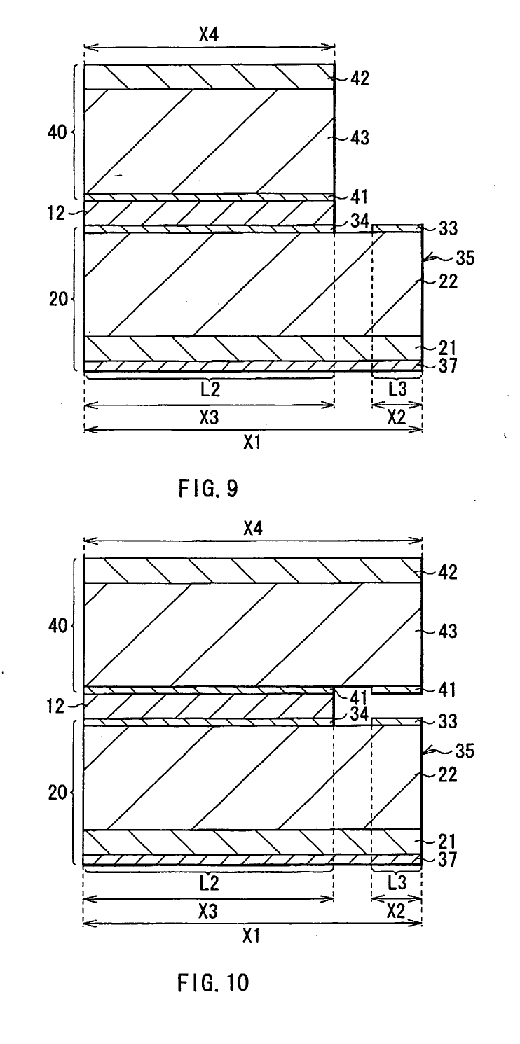

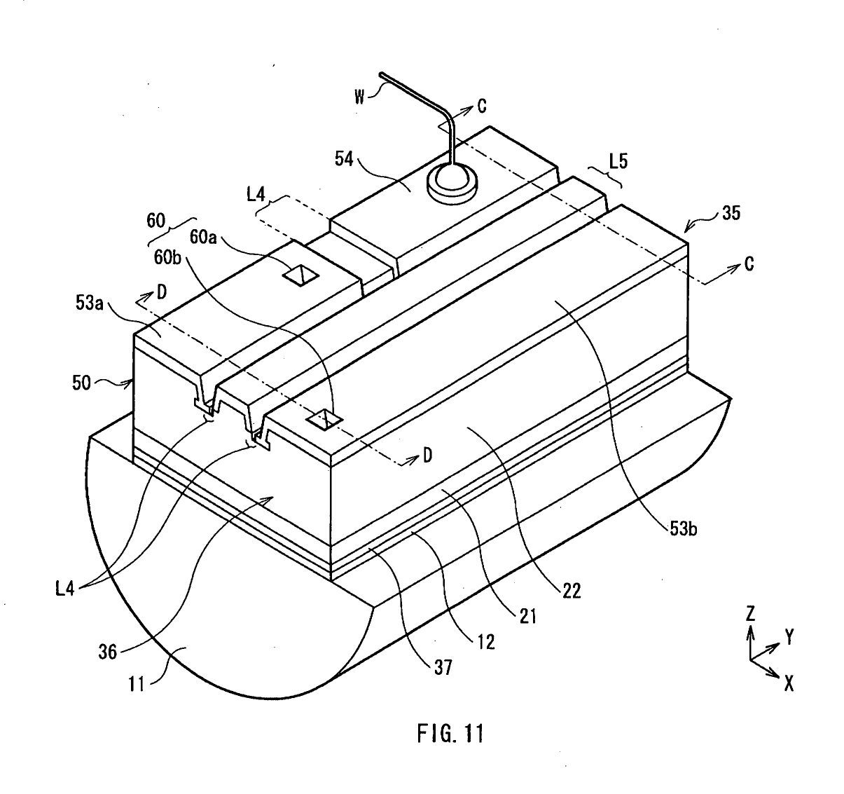

FIGS. 9 and 10 show sectional views of a laser diode device according to a modification of the first embodiment in a direction where the ridge 27 extends. FIGS. 9 and 10 are schematic views, so dimensions and shapes in FIGS. 9 and 10 are different from actual dimensions and shapes.

The laser diode device is distinguished from the laser diode device according to the above embodiment by the fact that a typical laser diode 40 (device) is mounted on the p-side electrodes 33 and 34 side of the laser diode 20 via the bonding layer 12. Therefore, the above difference will be mainly described in detail, and the same structures, functions and effects as those in the above embodiment will not be further described.

As described above, very little heat is generated in the saturable absorption region L3, so in the case where the saturable absorption region L3 is disposed on the emission-side end surface 35 side like the laser diode 20, it is not necessary to arrange a heat radiation mechanism near the emission-side end surface 35, and it is only necessary to arrange a heat radiation mechanism only in a region corresponding to the gain region L2 of the laser diode 20. Therefore, in the case where the bonding layer 12 and the laser diode 40 are used as heat radiation mechanisms, it is only necessary to bring the bonding layer 12 and the laser diode 40 into contact only with a region corresponding to the gain region L2 of the laser diode 20, and it is preferable to satisfy the following formula.

X3<X1−X2 (1)

In the formula, X1 is the length of the laser diode 20 in a direction where the ridge 27 extends; X2 is the length of the p-side electrode 33 in the direction where the ridge 27 extends; and X3 is the length of a contact region between the laser diode 20 and the laser diode 40 in the direction where the ridge 27 extends. As shown in FIG. 9, not only the length X3 of the contact region but also the length X4 of the laser diode 40 in the extending direction are reduced to be the same as the length of the above contact region, thereby the size of the laser diode 40 can be reduced, and manufacturing costs can be reduced. The above formula (1) is applicable to the case where a heat sink (a heat radiation section) is used instead of the laser diode 40.

As shown in FIGS. 9 and 10, it is preferable that surfaces of the laser diode 20 and the laser diode 40 on a side opposite to a side where the substrate is disposed are brought into contact with each other. It is because when they are brought into contact with each other not via the substrate, they can more efficiently use a device to be contacted as a heat radiation mechanism. Moreover, the surfaces on the side opposite to the side where the substrate is disposed can be brought into contact with each other, because it is not necessary to bond a wire to the p-side electrode 33.

Thereby, in the modification, a laser diode device in which the laser diode 40 is mounted on the p-side electrode 34 side of the laser diode 20 can be easily manufactured. In the modification, it is needless to say that the laser diode device in which the laser diode 40 is mounted on the n-side electrode 37 side of the laser diode 20, and in this case, the laser diode 40 may be mounted so as to face the p-side of the laser diode 40 up or down.

### Second Embodiment

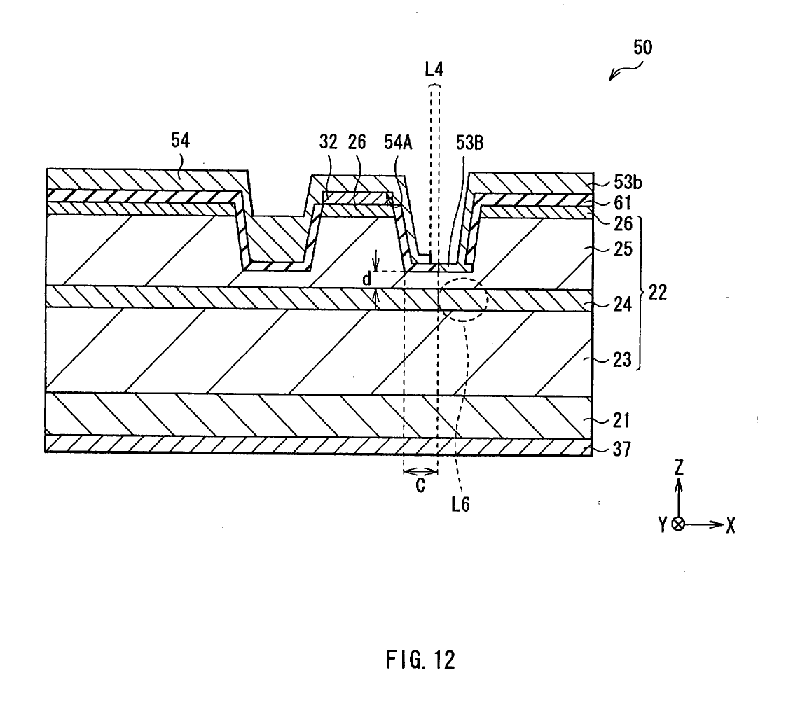

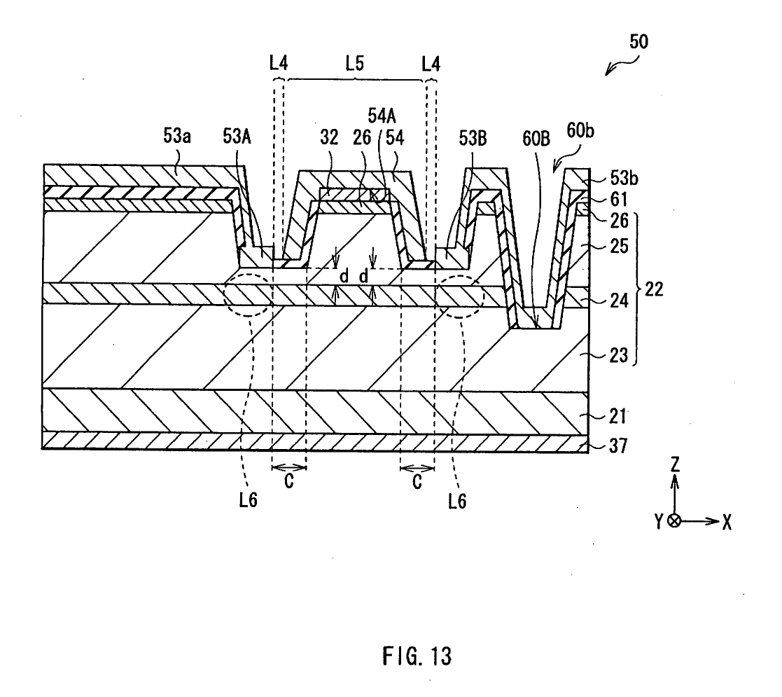

FIG. 11 shows the structure of a laser diode device according to a second embodiment of the invention. FIG. 12 shows a sectional view taken along an arrow C-C of FIG. 11, and FIG. 13 shows a sectional view taken along an arrow D-D of FIG. 11. FIGS. 11 through 13 show schematic views, so dimensions and shapes in FIGS. 11 through 13 are different from actual dimensions and shapes.

The laser diode device is formed through mounting a laser diode 50 on the heat sink 11 (a heat radiation section) with the bonding layer 12 in between so as to face the p-side of the laser diode 50 up. The laser diode 50 is distinguished from the laser diode 20 including the saturable absorption region L3 in a part of a region corresponding to a predetermined region of the ridge 27 by the fact that a saturable absorption region L6 is included in a region corresponding to the groove 28. Therefore, the above difference will be mainly described in detail, and the same structures, functions and effects as those in the above embodiment will not be further described.

In the semiconductor layer 22, each of holes 60 (60a and 60b) with a depth from the p-type cladding layer 25 to the n-type cladding layer 23 is formed in each of regions expanding on both sides of the W ridge structure. The hole 60a is formed in a region where a p-side electrode 53a which will be described later will be formed at a predetermined distance or over from a region where the W ridge structure is formed in the semiconductor layer 22, and the hole 60b is formed in a region where a p-side electrode 53b will be formed at a predetermined distance or over from the region where the W ridge structure is formed in the semiconductor layer 22.

An insulating film 61 is formed on a surface of the p-type cladding layer 25 including both side surfaces of the ridge 27, side surfaces of the grooves 28 and a part of the bottom surfaces of the grooves 28 and side surfaces of the holes 60 (60a and 60b). In other words, the active layer 24 in the holes 60 (60a and 60b) is covered with the insulating film 61, and the top surface of the ridge 27, a part (a region where the p-type cladding layer 25 is exposed) of the bottom surfaces of the grooves 28, bottom portions 60A and 60B (regions where the n-type cladding layer 23 is exposed) of the holes 60 (60a and 60b) are not covered with the insulating film 61. The insulating film 61 has, for example, a structure in which SiO₂ and Si are laminated in this order.

P-side electrodes 53 (53a and 53b) (first electrodes) and a p-side electrode 54 (a second electrode) are formed on a surface including the surfaces of the insulating film 61 and the p-side contact electrode 32 and inner surfaces of the holes 60 (60a and 60b) with a separation region L4 in between.

The p-side electrode 54 is formed on the surface of a region where the holes 60 (60a and 60b) are not formed in the insulating film 61 and a surface of the p-side contact electrode 32. Therefore, the p-side electrode 54 is electrically connected to the p-type contact layer 26 of the ridge 27 via the p-side contact electrode 32. Hereinafter, a portion electrically connected to the p-type contact layer 26 of the ridge 27 in the p-side electrode 54 is called a contact portion 54A.

The p-side electrode 53a is formed on a region where the hole 60a is formed in the insulating film 61, and the p-side electrode 53b is formed on a region where the hole 60b is formed in the insulating film 61. Therefore, the p-side electrodes 53 (53a and 53b) are electrically connected not only to the p-type contact layer 26 of the ridge 27 via the p-side contact electrode 32 but also to the n-type cladding layer 23 via the bottom portions 60A and 60B (connecting portions). Therefore, the p-side electrodes 53 (53a and 53b) have the same potential (zero volts) as the n-type cladding layer 23. The p-side electrodes 53 (53a and 53b) are isolated from the active layer 24 by the insulating film 61 formed on the side surfaces of the holes 60 (60a and 60b). Hereinafter, a portion electrically connected to the p-type cladding layer 25 of the groove 28 in the p-side electrode 53a is called a contact portion 53A, and a portion electrically connected to the p-type cladding layer 25 of the groove 28 in the p-side electrode 53b is called a contact portion 53B.

A distance c from the edge of the ridge 27 to the contact portion 53A and the contact portion 53B preferably satisfies the following formula in the case where a distance from the active layer 24 to the contact portion 53A and the contact portion 53B is d.

c≧18d (2)

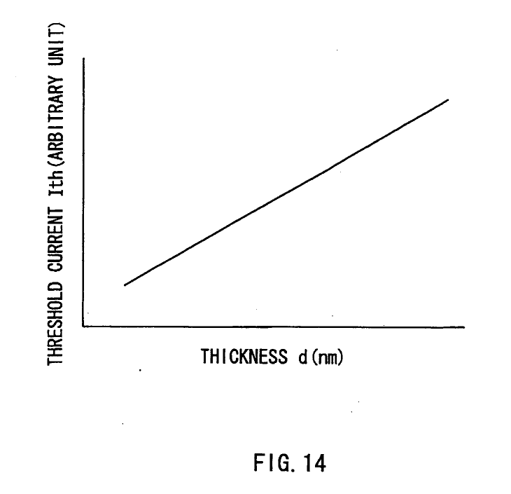

In general, when the distance d increases, a current confining function in the ridge 27 is weakened, and the width of a current injection region (a gain region L5) of the active layer 24 is widened, so as shown in FIG. 14, a threshold current Ith becomes larger. Therefore, in general, the distance d is narrowed to approximately 50 nm to 100 nm so as to narrow the current injection region (the gain region L5) of the active layer 24. However, even if the distance d is narrowed in such a manner, the width of the current injection region (the gain region L5) of the active layer 24 is wider than the width of the ridge 27, so when the contact portion 53A or the contact portion 53B is arranged beside the ridge 27, a current supplied from the p-side electrode 54 is not supplied to the active layer 24, and is discharged to the p-side electrode 53, thereby a light emitting efficiency declines. Therefore, to prevent the current supplied from the p-side electrode 54 from being not supplied to the active layer 24 and being discharged to the p-side electrode 53, it is necessary to arrange the saturable absorption region L6 at some distance from the edge of the ridge 27.

Moreover, the separation region L4 includes a strip-shaped region formed in one of regions which are spread out from both sides of the W ridge structure and extend in a direction perpendicular to the axial direction and a strip-shaped region which is formed in a part of the bottom surface of the groove 28 and extends in the axial direction, and the separation region L4 is formed so as to spatially separate the p-side electrodes 53 (53a and 53b) and the p-side electrode 54 from each other and not to electrically short-circuit them. More specifically, in the separation region L4, the p-side contact layer 26 is removed, and the surface of the separation region L4 is covered with the insulating film 61.

Thereby, the p-side electrode 54 can inject a current into the active layer 24 via the contact portion 54A, so a region corresponding to the contact portion 54A in the active layer 24 has a function as a so-called gain region L5. On the other hand, the p-side electrodes 53 (53a and 53b) can draw a current (photocurrent) from the active layer 24 via the contact portions 53A and 53B, and can discharge the current from the active layer 24 via the bottom portions 60A and 60B of the holes 60 (60a and 60b), the n-type cladding layer 23 and the heat sink 11, so a region corresponding to the contact portions 53A and 53B in the active layer 24 has a function as a so-called saturable absorption region L6.

In this case, “a function as a gain region L5” means a function of amplifying light emitted by an injected carrier, and “a function as a saturable absorption region L6” means a function of absorbing light emitted in the gain region L5. Therefore, the laser diode 50 according to the embodiment can produce self-oscillation (pulsation) by an interaction between the gain region L5 and the saturable absorption region L6.

The p-side electrodes 53 (53a and 53b) are electrically connected to the n-type cladding layer 23 having the same potential (zero volts) as a ground via the bottom portions 60A and 60B, so the p-side electrodes 53 can have zero volts without wire bonding. In other words, it is not necessary to directly bond a wire to the p-side electrodes 53 (53a and 53b), so in a step of mounting the laser diode 50, a step of bonding a wire to the p-side electrodes 53 (53a and 53b) can be omitted.

Moreover, it is only necessary for the contact portions 53A and 53B to be disposed in a region sandwiched by a resonator including the emission-side end surface 35 and the reflection-side end surface 36, so the contact portions 53A and 53B may be formed only in a part of the bottom portion in one of two grooves 28 formed on both sides of the ridge 27; however, as in the embodiment, the contact portions 53A and 53B may be formed in both of the bottom portions of two grooves 28 formed on both sides of the ridge 27.

In the laser diode 50, when a voltage having a predetermined potential difference is applied between the p-side electrode 54 and the n-side electrode 37, a current confined by the ridge 27 is injected into the gain region L5 (a light emission region) of the active layer 24, thereby light emission by electron-hole recombination occurs. The light is reflected by a pair of reflecting mirror films, and causes laser oscillation with a wavelength with a round-trip phase shift of an integral multiple of 2π, and the light is outputted to outside as a beam.

At this time, the p-side electrodes 53 (53a and 53b) are electrically connected to the ground via the bottom portions 60A and 60B so as to have zero volts, so light emitted in the gain region L5 is absorbed in the saturable absorption region L6 corresponding to the p-side electrodes 53 (53a and 53b) in the active layer 24 to be converted into a current (photocurrent). The current is discharged to the ground via the p-side electrodes 53 (53a and 53b) and the bottom portions 60A and 60B. Then, an interaction between the gain region L5 and the saturable absorption region L6 is initiated to cause self-oscillation.

Thus, in the laser diode 50 according to the embodiment, the semiconductor layer 22 includes the bottom portions 60A and 60B, and the n-type cladding layer 23 and the p-side electrodes 53 (53a and 53b) are electrically connected to each other via the bottom portions 60A and 60B, thereby the p-side electrodes 53 (53a and 53b) can have the same potential (zero volts) as the ground, so self-oscillation can be produced without wire bonding. Moreover, as it is not necessary to bond a wire to the p-side electrodes 53 (53a and 53b), so the laser diode 50 can be easily mounted. Therefore, in the embodiment, a laser diode device in which the heat sink 11 or the like is mounted on the laser diode 50 can be easily manufactured.

### [First Modification]

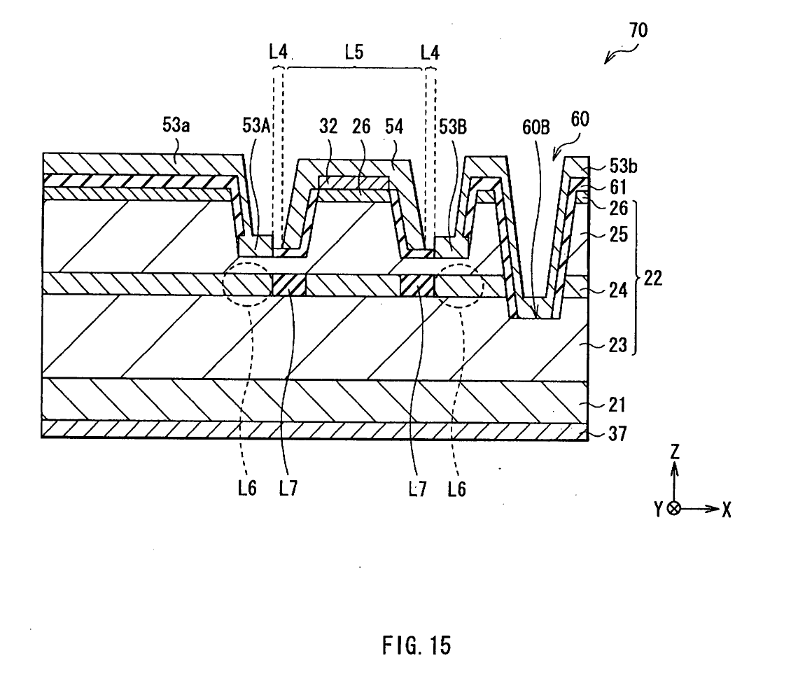

FIG. 15 shows the structure of a laser diode device according to a first modification of the second embodiment. FIG. 15 is a schematic view, so dimensions and shapes in the FIG. 15 are different from actual dimensions and shapes. A laser diode 70 according to the modification is distinguished from the second embodiment by the fact that an ion implantation region L7 is included in a region corresponding to a region between the ridge 27 and the contact portion 53A in the active layer 24. The above difference will be mainly described in detail, and the same structures, functions and effects as those in the second embodiment will not be further described.

As described above, the ion implantation region L7 is formed in a region corresponding to a region between the ridge 27 and the contact portion 53A in the active layer 24. The ion implantation region L7 is formed through injecting ions including at least one kind selected from the group consisting of silicon (Si), aluminum (Al), oxygen (O) and boron (B) into the active layer 24 from the bottom surface of the groove 28 after forming the groove 28. Therefore, in the ion implantation region L7, a smaller band gap than an energy band gap in the other region of the active layer 24 is formed, thereby light emitted in the gain region L5 (a light emission region) of the active layer 24 can be more efficiently absorbed to be converted into a current (photocurrent).

Thus, in the laser diode device according to the modification, the laser diode 70 includes the ion implantation region L7, so emitted light generated in the gain region L5 (the light emission region) of the active layer 24 is more efficiently absorbed to be converted into a current (photocurrent), so a reduction in self-oscillation can be prevented.

### [Second Modification]

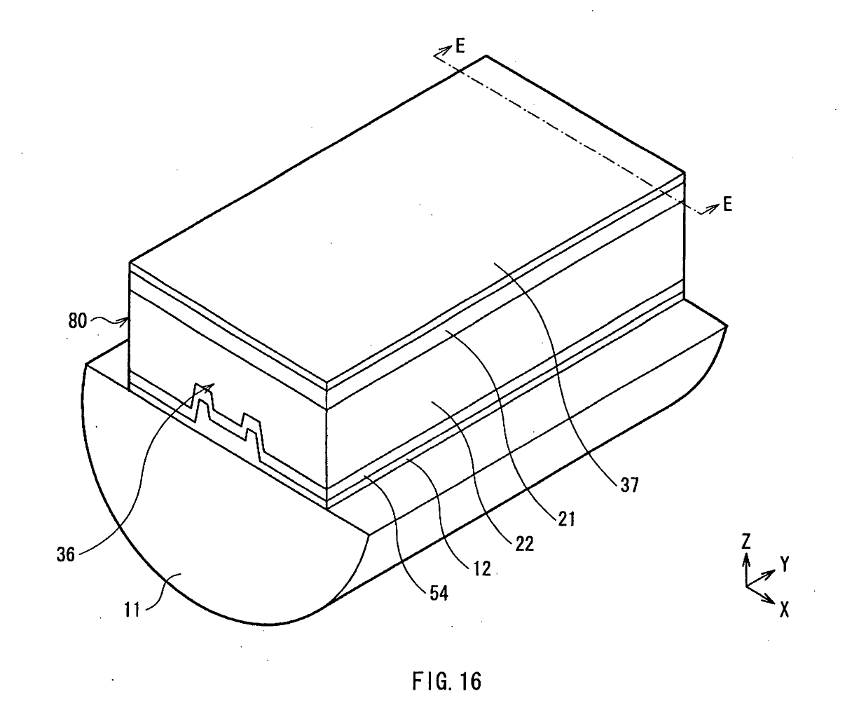

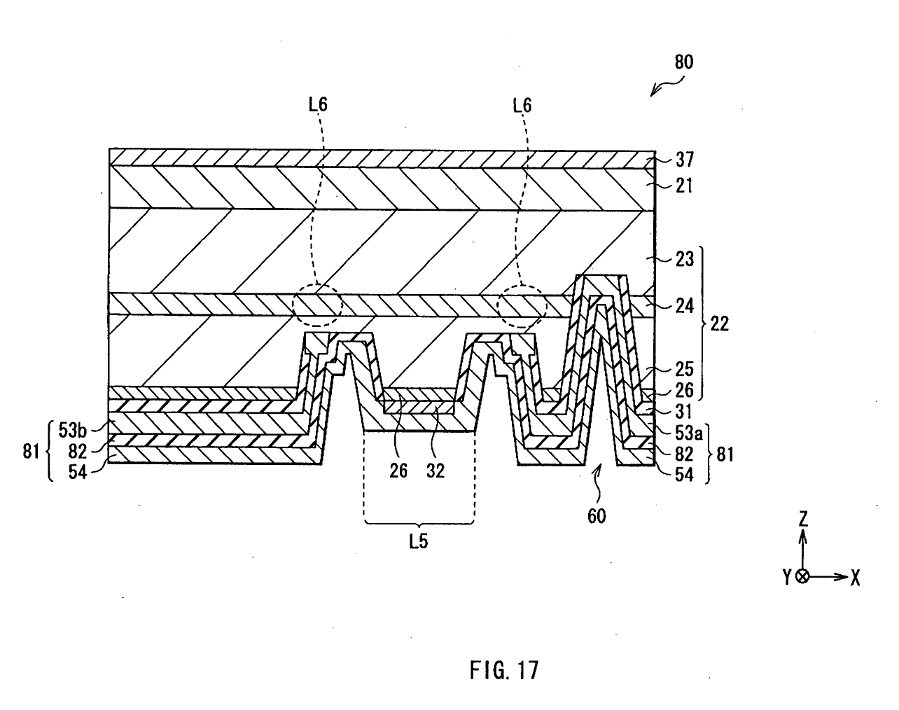

FIG. 16 shows the structure of a laser diode device according to a second modification of the second embodiment. FIG. 17 shows a sectional view taken along an arrow E-E of FIG. 16. FIGS. 16 and 17 are schematic views, so dimensions and shapes in FIGS. 16 and 17 are different from actual dimensions and shapes.

The laser diode device is distinguished from the laser diode device according to the second embodiment by the fact that a laser diode 80 is mounted on the heat sink 11 (a heat radiation section) with the bonding layer 12 in between so as to face the p-side of the laser diode 80 down. Moreover, the laser diode 80 is distinguished from the laser diode 50 according to the second embodiment by the fact that a multilayer wiring structure 81 in which the p-side electrodes 53 and 54 are laminated with an insulating film 82 in between is included. Therefore, the above differences will be mainly described in detail, and the same structures, functions and effects as those in the second embodiment will not be further described.

In the multilayer wiring structure 81, the insulating film 82 is formed so as to be laid over the p-side electrodes 53 (53a and 53b), and the p-side electrode 54 is formed on the insulating film 82 so as to extend. Thereby, the p-side electrodes 53 (53a and 53b) are isolated from the p-side electrode 54.

Thus, in the laser diode 80 according to the modification, as the multilayer wiring structure 81 is included, only the p-side electrode 54 out of the p-side electrodes 53 and 54 is exposed to outside. Therefore, the heat sink 11 or the like is more easily mounted on the p-side electrode 54 side. Thus, in the modification, the laser diode device in which the heat sink 11 or the like is mounted on the p-side electrode 54 of the laser diode 80 can be easily manufactured, and compared to the case where the heat sink 11 is mounted on the n-side electrode 37 side, the heat radiation efficiency and laser characteristics can be improved.

Although the present invention is described referring to the embodiments and the modifications, the invention is not limited to the embodiments and the modifications, and can be variously modified.

For example, in the above embodiments, the case where the Group III-V nitride semiconductor is used as the material of the semiconductor layer 22 is described; however, a GaInP-based (red) semiconductor, an AlGaAs-based (infrared) semiconductor or the like may be used.

Moreover, the current confinement structure is not limited to an index guide type, and any other current confinement structure such as a gain guide type may be used.

Further in the embodiments and the modifications, the top portion of the semiconductor layer 22 has a p-type polarity and the bottom portion of the semiconductor layer 22 has an n-type polarity; however, the polarities may be reversed. The manufacturing method is not limited to the manufacturing methods described in detail in the above embodiments, and any other manufacturing method may be used.

In the first and second embodiments and the first modification of the second embodiment, the case where the laser diodes 20, 50 and 70 are mounted so as to face the p-sides of them up is described; however, the p-sides may be faced down. The laser diodes 20, 50 and 70 are preferably mounted so as to face the p-sides of them down, because the heat radiation efficiency and the laser characteristics can be improved, compared to the case where they are mounted so as to face the p-sides of them up. In the second modification of the second embodiment, the laser diode 80 may be mounted so as to face the p-side of the semiconductor layer 80 up.

It should be understood by those skilled in the art that various modifications, combinations, sub-combinations and alterations may occur depending on design requirements and other factors insofar as they are within the scope of the appended claims or the equivalents thereof.

What is claimed is:

1. A laser diode comprising:
an active layer between a first conductivity type layer and a second conductivity type layer, said second conductivity type layer being between a plurality of electrodes and said active layer;
a hole through said second conductivity type layer extending to a bottom portion, said bottom portion being at a portion of said first conductivity type layer;
an insulating film on said second conductivity type layer and a side surface of said hole, said insulating film physically isolating said plurality of electrodes from said active layer.

2. The laser diode according to claim 1, wherein a substrate is between said first conductivity type layer and a first conductivity-side electrode, a bonding layer being between said first conductivity-side electrode and a heat sink.

3. The laser diode according to claim 1, wherein said plurality of electrodes is on a ridge, said ridge being a portion of said second conductivity type layer.

4. The laser diode according to claim 3, wherein said ridge is stripe-shaped.

5. The laser diode according to claim 3, wherein said ridge extends in an axial direction, said active layer emitting light along said axial direction.

6. The laser diode according to claim 5, wherein said hole extends to said bottom portion in a direction other than said axial direction.

7. The laser diode according to claim 3, wherein openings within said insulating film expose said bottom portion and contact regions, said contact regions being on said ridge.

8. The laser diode according to claim 7, wherein a second conductivity-side electrode is on said insulating film, said second conductivity-side electrode being in physical contact with said bottom portion and one of the contact regions.

9. The laser diode according to claim 7, wherein another second conductivity-side electrode is on said insulating film, said another second conductivity-side being electrode physically isolated from said bottom portion while being in physical contact with another of the contact regions.

10. The laser diode according to claim 9, wherein an area of said one of the contact regions is less than an area of said another of the contact regions.

11. The laser diode according to claim 9, wherein said second conductivity-side electrode is electrically isolated from said another second conductivity-side electrode.

12. The laser diode according to claim 3, wherein said insulating film on said ridge is between one of said electrodes and another of said electrodes.

13. The laser diode according to claim 3, wherein said ridge is between grooves, said grooves extending only into said second conductivity type layer.

14. The laser diode according to claim 3, wherein said ridge extends along a separation region, a gain region, and an absorption region.

15. The laser diode according to claim 14, wherein said separation region is between said gain region and said absorption region.

16. The laser diode according to claim 14, wherein said hole is within said absorption region.

17. The laser diode according to claim 14, wherein said absorption region is between an emission-side end surface and said separation region, said gain region being between said separation region and a reflection-side end surface.

18. The laser diode according to claim 17, wherein a light beam is emissible from said emission-side end surface.

19. The laser diode according to claim 17, wherein light generated in said gain region of said active layer, said light traveling between said emission-side end surface and said reflection-side end surface.

20. The laser diode according to claim 1, wherein said active layer includes an ion implantation region, said ion implantation region including a dopant from the group consisting of silicon (Si), aluminum (Al), oxygen (O) and boron (B).
